(19) United States
(12) Patent Application Publication
(10) Pub. No.: US 2026/0344426 A1
(43) Pub. Date: Oct. 29, 2026

(54) STACKED THERMAL INTERFACE COMPONENTS COMPRISING HIGH THERMAL CONDUCTIVITY LAYERS FOR SEMICONDUCTOR PACKAGING

(71) Applicant: Entegris, Inc., Billerica, MA (US)

(72) Inventors: Niraj Mahadev, Milpitas, CA (US); Rajiv K. Singh, Newberry, FL (US); Aditya Dilip Verma, San Jose, CA (US); Sunny De, Oviedo, FL (US); Sridevi R. Alety, Fremont, CA (US)

(21) Appl. No.: 19/656,476

(22) Filed: Apr. 23, 2026

Related U.S. Application Data
(60) Provisional application No. 63/794,291, filed on Apr. 24, 2025.

(51) Int. Cl. H10W 40/25; H10B 80/00; H10D 80/30; H10W 40/20; H10W 72/30; H10W 90/00; H10W 90/20

(52) U.S. Cl. CPC H10W 40/255; H10W 40/233; H10W 40/235; H10W 40/253; H10W 40/254; H10W 72/322; H10W 72/324; H10W 72/353; H10W 72/355; H10W 72/365; H10W 90/288; H10W 90/734; H10B 80/00; H10D 80/30

(57) ABSTRACT

A thermal interface component for a semiconductor device packaging structure includes a first layer comprising a thermal interface material having a thermal conductivity of at least 200 W·m⁻¹·K⁻¹ and a second layer having a thermal conductivity from 0.1% to 80% of the thermal conductivity of the first layer. The first layer is supported by the second layer, and a thickness of the first layer is greater than a thickness of the second layer. The thermal interface component is dimensioned for integration into a semiconductor device packaging structure. The first layer may comprise diamond, silicon carbide, aluminum nitride, or boron nitride. A third layer may be disposed on a side of the first layer opposite the second layer such that the first layer is disposed between the second and third layers. The first layer may be bonded directly or indirectly to at least one of the second layer or the third layer, optionally via an intervening metal layer.

### CROSS-REFERENCE TO RELATED APPLICATION

This application claims the benefit of and priority to U.S. Provisional Application No. 63/794,291 , filed Apr. 24, 2025, the contents of which are incorporated herein by reference in their entirety for all purposes.

### FIELD

The present disclosure relates to thermal interface components for semiconductor device packaging structures, and more particularly to multilayer thermal interface components comprising high thermal conductivity materials bonded to supporting layers for heat dissipation in semiconductor devices.

### BACKGROUND

Advanced semiconductor devices continue to experience escalating power densities as a result of transistor scaling, heterogeneous integration, and three-dimensional packaging architectures become more widely adopted. The resulting thermal loads impose stringent demands on heat spreading and heat dissipation structures positioned in close proximity to active semiconductor regions. Conventional thermal interface materials (TIMs), such as metal alloys, polymer-based greases, carbon composites, or ceramic fillers, often exhibit limitations in thermal conductivity, mechanical stability, or reliability when subjected to the high heat fluxes characteristic of modern high performance processors, power devices, and chiplet-based architectures.

### SUMMARY

The present disclosure relates to thermal interface components for semiconductor device packaging structures, and more particularly to multilayer thermal interface components comprising high thermal conductivity materials bonded to supporting layers for heat dissipation in semiconductor devices.

In one aspect, the present disclosure provides a thermal interface component for a semiconductor device packaging structure. The thermal interface component includes a first layer comprising a thermal interface material having a thermal conductivity of at least 200 W·m⁻¹·K⁻¹ and a second layer having a thermal conductivity from 0.1% to 80% of the thermal conductivity of the first layer. The first layer is supported by the second layer, and a thickness of the first layer is greater than a thickness of the second layer. The thermal interface component is dimensioned for integration into a semiconductor device packaging structure.

In another aspect, the present disclosure provides a semiconductor device comprising a thermal interface component. The thermal interface component includes a first layer comprising a thermal interface material having a thermal conductivity of at least 200 W·m⁻¹·K⁻¹ and at least a second layer having a thermal conductivity from 0.1% to 80% of the thermal conductivity of the first layer. The second layer supports the first layer, and a thickness of the first layer is greater than a thickness of the second layer.

The preceding summary is provided to facilitate an understanding of some of the features of the present disclosure and is not intended to be a full description. A full appreciation of the disclosure can be gained by taking the entire specification, claims, drawings, and abstract as a whole.

### DRAWINGS

The disclosure may be more completely understood in consideration of the following description of various illustrative embodiments in connection with the accompanying drawings, in which:

FIG. 1 is a schematic cross-sectional view of a thermal interface component including a diamond layer disposed between silicon layers and bonded via intervening layers, according to some embodiments;

FIG. 2 is a schematic cross-sectional view of a thermal interface component including a diamond layer disposed between silicon layers, with an intervening layer on one side of the diamond layer, according to some embodiments;

FIG. 3 is a schematic cross-sectional view of a thermal interface component illustrating an alternative placement of an intervening layer relative to a diamond layer, according to some embodiments;

FIG. 4 is a schematic cross-sectional view of a thermal interface component including a diamond layer directly bonded between silicon layers without an intervening layer, according to some embodiments;

FIG. 5 is a schematic cross-sectional view of the thermal interface component illustrating the plurality of diamond segments disposed between silicon layers, according to some embodiments; and

FIG. 6 is a schematic cross-sectional view of a semiconductor device including a plurality of semiconductor dies, one or more dielectric layers, an interposer, and a stacked thermal interface component disposed between a semiconductor die and an adjacent layer, according to some embodiments.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

As used herein, “have”, “having”, “include”, “including”, “comprise”, “comprising”, “contain”, and “containing” are open-ended linking verbs. As a result, an apparatus or method that “has”, “includes”, “comprises”, or “contains” one or more elements possesses those one or more elements but is not limited to possessing only those elements. Likewise, an element of an apparatus or a step of a method that “has”, “includes”, “comprises”, or “contains” one or more features possesses those one or more features but is not limited to possessing only those one or more features.

As used herein, the terms “about” and “approximately,” when used to modify a numerical value, mean within a tolerance of the stated numerical value. The tolerance may be determined based on the precision of the measurement technique used and/or based on known tolerances of the components or processes involved. For example, the terms “about” and “approximately” may indicate a range of plus or minus 10% of the stated value, or plus or minus 5% of the stated value, unless the context indicates otherwise.

When a numerical range is stated herein, including in the appended claims, such range is intended to include the endpoints of the range and all individual values and subranges that fall within the stated range. For example, a stated range of “1 to 10” is intended to include all individual values (e.g., 1, 1.5, 2, 3.7, 8, 10) and all subranges (e.g., 1 to 5, 2 to 8, 3 to 10) within the stated range. When a range is expressed as “at least” a particular value or “at most” a particular value, the range includes that value as a lower or upper bound, respectively, and extends to any higher or lower value consistent with the context.

When multiple ranges are disclosed for a given parameter, any lower bound of a disclosed range may be combined with any upper bound of any other disclosed range for the same parameter, and each such combination is intended as a separate disclosed range.

The terms “first,” “second,” “third,” and similar ordinal terms are used herein for identification purposes only and do not imply a particular order, importance, or hierarchy among the elements they modify unless expressly stated otherwise.

The following detailed description should be read with reference to the drawings in which similar elements in different drawings are numbered the same. The detailed description and the drawings, which are not necessarily to scale, depict illustrative embodiments and are not intended to limit the scope of the disclosure. The illustrative embodiments depicted are intended only as exemplary. Selected features of any illustrative embodiment may be incorporated into an additional embodiment unless clearly stated to the contrary.

Semiconductor devices can include a thermal interface component positioned between a heat-generating semiconductor region and a heat-spreader, substrate, interposer, or packaging layer. As used herein, a thermal interface material is a material positioned between a heat-generating component and a heat-dissipating component to reduce interfacial thermal resistance by improving thermal contact and facilitating heat transfer across the interface.

A thermal interface component, as described herein according to the various embodiments, can include a thermal interface material having a thermal conductivity of at least 200 W·m⁻¹·K⁻¹, at least 250 W·m⁻¹·K⁻¹, at least 300 W·m⁻¹·K⁻¹, at least 350 W·m⁻¹·K⁻¹, at least 400 W·m⁻¹·K⁻¹, at least 450 W·m⁻¹·K⁻¹, at least 500 W·m⁻¹·K⁻¹, at least 550 W·m⁻¹·K⁻¹, at least 600 W·m⁻¹·K⁻¹, at least 650 W·m⁻¹·K⁻¹, at least 700 W·m⁻¹·K⁻¹, at least 750 W·m⁻¹·K⁻¹, at least 800 W·m⁻¹·K⁻¹, at least 850 W·m⁻¹·K⁻¹, at least 900 W·m⁻¹·K⁻¹, at least 950 W·m⁻¹·K⁻¹, or of at least 1000 W·m⁻¹·K⁻¹.

In some embodiments, a thermal interface component for integration into a semiconductor device can include a first layer comprising a thermal interface material bonded, directly or indirectly, to at least a second layer forming a stacked component. In some cases, a thermal interface component can include a first layer comprising a thermal interface material bonded, directly or indirectly, to a second layer and a third layer forming a stacked component. The stacked thermal interface component can include one or more intervening layers between the first layer and one or both of the second and third layers.

The second layer and, when present, the third layer each can have a thermal conductivity that is less than that of the first layer comprising the thermal interface material. In some embodiments, the second layer and the third layer can each independently have a thermal conductivity that is from 0.1% to 80% of the thermal conductivity of the thermal interface material forming the first layer or any range or subrange between 0.1% to 80%. For example, a thermal conductivity of the second layer and the third layer can each independently range from 0.1% to 70%, 0.1% to 60%, 0.1% to 50%, 0.1% to 40%, 0.1% to 30%, 0.1% to 20%, 0.1% to 10%, 0.1% to 1%, 10% to 80%, 20% to 80%, 30% to 80%, 40% to 80%, 50% to 80%, 60% to 80%, or 70% to 80%.

In some embodiments, as will be described herein, a thermal interface component can include a thermal interface layer disposed between a second layer and a third layer. A bottom surface of the thermal interface layer can be bonded, directly or indirectly, to an upper surface of the second layer and an upper surface of the thermal interface layer can be bonded, directly or indirectly, to a lower surface of the third layer, such that the third layer is located on a side of the thermal interface layer opposite to that of the second layer.

In some embodiments, a thermal interface component includes a thermal interface layer bonded, directly or indirectly, to only a second layer in which the thermal interface layer forms the top or bottom of the thermal interface component. In some embodiments, a bottom surface of the thermal interface layer is bonded, directly or indirectly, to an upper surface of the second layer such that an upper surface of the thermal interface layer forms a top surface of the thermal interface component. In other embodiments an upper surface of the thermal interface layer is bonded, directly or indirectly, to a bottom surface of the second layer such that the upper surface of the second layer forms a top surface of the thermal interface component.

In embodiments where the thermal interface layer is bonded indirectly to the second and/or third layers, an intervening layer may be present. In some cases, the intervening layer can be a metal layer.

According to various embodiments, as described herein, a thickness of the thermal interface layer can be greater than a thickness of each of the second and third layers. A thickness of the thermal interface layer can range from 1 μm to 5000 μm or any range or subrange between. For example, a thickness of the thermal interface layer can range from 1 μm to 4000 μm, 1 μm to 3000 μm, 1 μm to 2000 μm, 1 μm to 1000 μm, 1 μm to 900 μm, 1 μm to 800 μm, 1 μm to 700 μm, 1 μm to 600 μm, 1 μm to 500 μm, 10 μm to 500 μm, 20 μm to 500 μm, 30 μm to 500 μm, 40 μm to 500 μm, 50 μm to 500 μm, 100 μm to 500 μm, 100 μm to 700 μm, 100 μm to 800 μm, 100 μm to 900 μm, or 100 μm to 1000 μm.

In some cases, each of the second or third layers can be provided as a thin film having a thickness ranging from 0.001 μm to 1000 μm or any range or subrange between. For example, the second and/or third layers can each have a thickness ranging from 0.001 μm to 1000 μm, or any range or subrange between 0.001 μm and 1000 μm. In some embodiments, for example, the third layer has a thickness of 0.001 μm to 200μm, 0.001 μm to 190 μm, 0.001 μm to 180 μm, 0.001 μm to 170 μm, 0.001 μm to 160 μm, 0.001 μm to 150 μm, 0.001 μm to 140 μm, 0.001 μm to 130 μm, 0.001 μm to 120 μm, 0.001 μm to 110 μm, 0.001 μm to 100 μm, 0.001 μm to 90 μm, 0.001 μm to 80 μm, 0.001 μm to 70 μm, 0.001 μm to 60 μm, 0.001 μm to 50 μm, 0.001 μm to 40 μm, 0.001 μm to 30 μm, 0.001 μm to 20 μm, 0.001 μm to 10 μm, 0.001 μm to 1 μm, 0.001 μm to 0.5 μm, 0.001 μm to 0.1 μm, 0.001 μm to 0.05 μm, 0.001 μm to 0.01 μm, 0.001 μm to 0.005 μm, 0.005 μm to 200 μm, 0.01 μm to 200 μm, 0.05 μm to 200 μm, 0.1 μm to 200 μm, 0.5 μm to 200 μm, 1 μm to 200 μm, 10 μm to 200 μm, 20 μm to 200 μm, 30 μm to 200 μm, 40 μm to 200 μm, 50 μm to 200 μm, 60 μm to 200 μm, 70 μm to 200 μm, 80 μm to 200 μm, 90 μm to 200 μm, 100 μm to 200 μm, 110 μm to 200 μm, 120 μm to 200 μm, 130 μm to 200 μm, 140 μm to 200 μm, 150 μm to 200 μm, 160 μm to 200 μm, 170 μm to 200 μm, 180 μm to 200 μm, or 190 μm to 200 μm. In some embodiments, the third layer has a thickness of 100 μm to 900 μm, 100 μm to 800 μm, 100 μm to 700 μm, 100 μm to 600 μm, 100 μm to 500 μm, 100 μm to 400 μm, 100 μm to 300 μm, 100 μm to 200 μm, 200 μm to 1000 μm, 300 μm to 1000 μm, 400 μm to 1000 μm, 500 μm to 1000 μm, 600 μm to 1000 μm, 700 μm to 1000 μm, 800 μm to 1000 μm, or 900 μm to 1000 μm.

In some embodiments, the thermal interface material can include diamond, silicon carbide, high thermal conductivity ceramic materials, boron-based materials, graphene-based materials or graphite-based materials. Exemplary high thermal conductivity ceramic materials can include aluminum nitride or beryllium oxide. Additionally, the thermal interface material can be monocrystalline or polycrystalline.

Diamond and silicon carbide have emerged as promising materials for thermal interface layers due to their high intrinsic thermal conductivity, wide bandgap, and favorable mechanical hardness. These attributes render both materials highly effective at transporting heat away from localized hotspots and maintaining stable performance under aggressive thermal cycling. Despite these advantages, practical integration of diamond and silicon carbide into semiconductor packaging stacks remains challenging.

One such challenge arises from the difficulty of forming low resistance thermal and mechanical bonds between diamond and adjacent materials such as silicon, silicon carbide, gallium nitride, dielectric passivation layers, metals, or composite interface layers. Because diamond surfaces possess distinct chemical and mechanical properties, interface adhesion can be insufficient without additional intermediate layers, which themselves introduce unwanted thermal boundary resistance. Furthermore, the substantial mismatch in thermal expansion coefficients between diamond and common semiconductor or packaging materials can generate interfacial stresses, potentially leading to delamination or cracking during device operation. Similar interfacial thermal resistance and thermo-mechanical reliability challenges can also arise when silicon carbide is employed as a rigid thermal interface material in stacked chip architectures.

Another challenge relates to fabrication constraints. Many high quality diamond deposition processes, such as chemical vapor deposition, are traditionally performed at temperatures that exceed allowable thermal budgets in back-end-of-line (BEOL) processing. Achieving diamond integration at substantially lower temperatures, while maintaining material quality, imposes processing and equipment challenges. Similar processing and equipment challenges are also present when attempting to integrate silicon carbide, particularly when high-quality silicon carbide films are desired within BEOL thermal budget constraints.

Vapor deposited diamond films—whether microcrystalline, nanocrystalline, or single crystal—typically exhibit substantial as-deposited surface roughness that may range from several nanometers to hundreds of microns depending on grain size and film thickness. Such roughness increases thermal boundary resistance (TBR), inhibits effective bonding to adjacent semiconductor or metallic layers, and reduces the reliability of the resulting interface. Additionally, diamond's extreme hardness and chemical inertness render it difficult to polish using conventional chemical mechanical polishing (CMP) techniques.

Vapor-deposited silicon carbide films—whether amorphous, polycrystalline, or epitaxial—can likewise exhibit non-negligible as-deposited surface roughness and microstructural non-uniformity arising from columnar growth, grain boundaries, or phase inhomogeneity. Such surface and microstructural features can increase thermal boundary resistance, complicate intimate contact with adjacent semiconductor, dielectric, or metallic layers, and degrade interfacial reliability, particularly when silicon carbide is employed as a rigid thermal interface material. In addition, the high hardness and chemical stability of silicon carbide limit the effectiveness of conventional chemical mechanical polishing processes, often requiring specialized abrasives, elevated pressures, or non-standard chemistries that increase process complexity and integration costs.

In some cases, the surfaces of diamond and silicon carbide layers typically exhibit high surface roughness due to grain boundaries, faceting, and intrinsic nucleation morphology. Without modification, this roughness results in incomplete contact with adjacent layers, increased thermal boundary resistance (TBR), and poor mechanical reliability. Accordingly, the present disclosure provides structures and methods that employ diamond or silicon carbide surfaces that have been chemically mechanically polished to achieve ultra-low surface roughness and reduced defect density.

In some embodiments, the thermal interface material can include diamond and/or silicon carbide as the thermal interface material. Diamond, when used, may be single-crystal, polycrystalline, microcrystalline, nanocrystalline, or super-nanocrystalline, and may likewise be provided as a bulk component. Silicon carbide, when used, may also be present as a bulk component. As used herein, the term bulk component refers to a monolithic, self-supporting solid body of a thermally conductive material having a thickness sufficient such that heat transfer occurs predominantly through the body of the material itself. The bulk component is distinct from thin films, coatings, foils, greases, gels, phase-change materials, or polymer-based thermal interface materials containing dispersed filler particles. In some embodiments, the bulk component is provided as a substrate, wafer, plate, or slab forming part of a thermal interface component. Silicon carbide, when used, may be single crystalline or polycrystalline.

In some embodiments, the first layer can include diamond as the thermal interface material and thus be a diamond layer. The diamond from which the thermal interface layer is formed can be monocrystalline or polycrystalline. The diamond layer may be continuous or patterned and may include one or more regions of diamond separated by regions of another material, such as silicon or silicon carbide or an interfacial material, provided that diamond is present within the layer.

In some embodiments, the diamond layer includes only diamond with no other materials present in the layer. The diamond can be monocrystalline or polycrystalline diamond. The diamond is provided in a form of a diamond wafer or substrate having a first continuous diamond surface opposite a second continuous diamond surface. In some embodiments, at least one of the first or the second continuous diamond surfaces is polished.

In some embodiments, the diamond layer comprises a plurality of discrete diamond segments disposed between the second layer and the third layer of the thermal interface component as described herein. Each of the plurality of diamond segments may have at least one surface that is bonded, directly or indirectly, to at least one of the second layer, the third layer, or both. In some embodiments, each of the plurality of diamond segments has a first surface and a second surface opposite the first surface, wherein the first surface is directly bonded to the second layer and the second surface is directly bonded to the third layer. In such embodiments, the diamond segments collectively form a diamond layer that is sandwiched between the second layer and the third layer. In some embodiments, the plurality of diamond segments is arranged such that portions of the second layer, the third layer, or both are exposed between adjacent diamond segments. For example, in some embodiments, the plurality of diamond segments does not fully cover the second layer and/or does not fully cover the third layer. In cases where the diamond layer is bonded indirectly to the second and/or third layers, an intervening layer may be present. In some embodiments, the intervening layer can be a metal layer.

In other embodiments, the diamond layer is provided in the form of a plurality of discrete diamond segments that are laterally defined using a damascene-type process. In such embodiments, the plurality of discrete diamond segments collectively forms a diamond layer that is disposed between, and sandwiched by, the second layer and the third layer. The discrete diamond segments may be positioned adjacent to one another or spaced apart from one another within the plane of the diamond layer. In some embodiments, the plurality of diamond segments is arranged in a periodic array, while in other embodiments the plurality of diamond segments is arranged in a non-periodic array, including a random arrangement. In some embodiments, each of the plurality of diamond segments is itself a continuous diamond region forming a portion of the diamond layer. Each diamond segment may include a first surface and a second surface opposite the first surface, wherein one or both of the first surface and the second surface are polished surfaces.

The plurality of diamond segments, as discussed herein, can be provided in at least one of a polygonal shape, a circular shape, or any combination thereof. In some embodiments, at least one of the plurality of diamond segments is provided in a shape of at least one of a regular polygon, an irregular polygon, a convex polygon, a concave polygon, or any combination thereof. Non-limiting examples of polygons include, for example and without limitation, at least one of a triangle, a quadrilateral (e.g., a square, a rectangle, etc.), a pentagon, a hexagon, a heptagon, an octagon, or any combination thereof, among others. Non-limiting examples of circular shapes include, for example and without limitation, at least one of a disc, an annulus, an oval, or any combination thereof. It will be appreciated that the diamond layer can also be provided in any one or more of the shapes disclosed herein.

In some embodiments, the plurality of diamond segments comprises 2 diamond segments to 1000 diamond segments, or any range or subrange between 2 diamond segments and 1000 diamond segments. For example, in some embodiments, the plurality of diamond segments comprises 2 to 1000, 2 to 950, 2 to 900, 2 to 850, 2 to 800, 2 to 750, 2 to 700, 2 to 650, 2 to 600, 2 to 550, 2 to 500, 2 to 450, 2 to 400, 2 to 350, 2 to 300, 2 to 250, 2 to 200, 2 to 150, 2 to 100, 2 to 50, 2 to 40, 2 to 30, 2 to 20, 2 to 10, 5 to 1000, 50 to 1000, 100 to 1000, 150 to 1000, 200 to 1000, 250 to 1000, 300 to 1000, 350 to 1000, 400 to 1000, 450 to 1000, 500 to 1000, 550 to 1000, 600 to 1000, 650 to 1000, 700 to 1000, 750 to 1000, 800 to 1000, 850 to 1000, 900 to 1000, or 950 to 1000 diamond segments.

In some embodiments, a thickness of the diamond layer is greater than a thickness of the second layer and, when present, the third layer of the thermal interface component as described herein. A thickness of the diamond layer can range from 1 μm to 5000 μm or any range or subrange between. For example, a thickness of the diamond layer can range from 1 μm to 4000 μm, 1 μm to 3000 μm, 1 μm to 2000 μm, 1 μm to 1000 μm, 1 μm to 900 μm, 1 μm to 800 μm, 1 μm to 700 μm, 1 μm to 600 μm, 1 μm to 500 μm, 10 μm to 500 μm, 20 μm to 500 μm, 30 μm to 500 μm, 40 μm to 500 μm, 50 μm to 500 μm, 100 μm to 500 μm, 100 μm to 700 μm, 100 μm to 800 μm, 100 μm to 900 μm, or 100 μm to 1000 μm.

In some embodiments, a surface roughness average (Rₐ) of at least one surface (upper or bottom) of the diamond layer is 0.1 nm to 100 nm, or any range or subrange between 0.1 nm and 100 nm. For example, in some embodiments, the surface roughness average of at least one surface of the diamond layer is 0.1 nm to 90 nm, 0.1 nm to 80 nm, 0.1 nm to 70 nm, 0.1 nm to 60 nm, 0.1 nm to 50 nm, 0.1 nm to 40 nm, 0.1 nm to 30 nm, 0.1 nm to 20 nm, 0.1 nm to 10 nm, 0.1 nm to 1 nm, 10 nm to 100 nm, 20 nm to 100 nm, 30 nm to 100 nm, 40 nm to 100 nm, 50 nm to 100 nm, 60 nm to 100 nm, 70 nm to 100 nm, 80 nm to 100 nm, or 90 nm to 100 nm.

In some embodiments, a thermal interface component for integration into a semiconductor device can include a silicon carbide layer bonded, directly or indirectly, to at least one of a second layer, a third layer, or both. For example, the silicon carbide layer may be bonded, directly or indirectly, to only the second layer forming a bilayer structure in which the silicon carbide forms the top or bottom of the structure. In other embodiments, the silicon carbide is bonded, directly or indirectly, to both the second and third layers forming a sandwich-like structure with the silicon carbide disposed between the second and third layers. In cases where the silicon carbide is bonded indirectly to the second and/or third layers, an intervening layer may be present. In some embodiments, the intervening layer can be a metal layer. The silicon carbide layer may be continuous or patterned and may include one or more regions of silicon carbide separated by regions of another material, such as diamond or an interfacial material, provided that silicon carbide is present within the layer.

In some embodiments, the silicon carbide layer includes only silicon carbide with no other materials present in the layer. The silicon carbide is provided in a form of a silicon carbide wafer or substrate having a first continuous silicon carbide surface opposite a second continuous silicon carbide surface. In some embodiments, at least one of the first or the second continuous silicon carbide surfaces is polished.

In some embodiments, the silicon carbide layer comprises a plurality of discrete silicon carbide segments disposed between a second layer and a third layer. Each of the plurality of silicon carbide segments may have at least one surface that is bonded, directly or indirectly, to at least one of the second layer, the third layer, or both. In some embodiments, each of the plurality of silicon carbide segments has a first surface and a second surface opposite the first surface, wherein the first surface is directly bonded to the second layer and the second surface is directly bonded to the third layer. In such embodiments, the silicon carbide segments collectively form a silicon carbide layer that is sandwiched between the second layer and the third layer. In some embodiments, the plurality of silicon carbide segments is arranged such that portions of the second layer, the third layer, or both are exposed between adjacent silicon carbide segments. For example, in some embodiments, the plurality of silicon carbide segments does not fully cover the second layer and/or does not fully cover the third layer. In cases where the silicon carbide is bonded indirectly to the second and/or third layers, an intervening layer may be present. In some embodiments, the intervening layer can be a metal layer.

In other embodiments, the silicon carbide layer is provided in the form of a plurality of discrete silicon carbide segments that are laterally defined using a damascene-type process. In such embodiments, the plurality of discrete silicon carbide segments collectively forms a silicon carbide layer that is disposed between, and sandwiched by, the second layer and the third layer. The discrete silicon carbide segments may be positioned adjacent to one another or spaced apart from one another within the plane of the silicon carbide layer. In some embodiments, the plurality of silicon carbide segments is arranged in a periodic array, while in other embodiments the plurality of silicon carbide segments is arranged in a non-periodic array, including a random arrangement. In some embodiments, each of the plurality of silicon carbide segments is itself a continuous silicon carbide region forming a portion of the silicon carbide layer. Each silicon carbide segment may include a first surface and a second surface opposite the first surface, wherein one or both of the first surface and the second surface are polished surfaces.

The plurality of silicon carbide segments, as discussed herein, can be provided in at least one of a polygonal shape, a circular shape, or any combination thereof. In some embodiments, at least one of the plurality of silicon carbide segments is provided in a shape of at least one of a regular polygon, an irregular polygon, a convex polygon, a concave polygon, or any combination thereof. Non-limiting examples of polygons include, for example and without limitation, at least one of a triangle, a quadrilateral (e.g., a square, a rectangle, etc.), a pentagon, a hexagon, a heptagon, an octagon, or any combination thereof, among others. Non-limiting examples of circular shapes include, for example and without limitation, at least one of a disc, an annulus, an oval, or any combination thereof. It will be appreciated that the silicon carbide can also be provided in any one or more of the shapes disclosed herein.

In some embodiments, the plurality of silicon carbide segments comprises 2 silicon carbide segments to 1000 silicon carbide segments, or any range or subrange between 2 silicon carbide segments and 1000 silicon carbide segments. For example, in some embodiments, the plurality of silicon carbide segments comprises 2 to 1000, 2 to 950, 2 to 900, 2 to 850, 2 to 800, 2 to 750, 2 to 700, 2 to 650, 2 to 600, 2 to 550, 2 to 500, 2 to 450, 2 to 400, 2 to 350, 2 to 300, 2 to 250, 2 to 200, 2 to 150, 2 to 100, 2 to 50, 2 to 40, 2 to 30, 2 to 20, 2 to 10, 5 to 1000, 50 to 1000, 100 to 1000, 150 to 1000, 200 to 1000, 250 to 1000, 300 to 1000, 350 to 1000, 400 to 1000, 450 to 1000, 500 to 1000, 550 to 1000, 600 to 1000, 650 to 1000, 700 to 1000, 750 to 1000, 800 to 1000, 850 to 1000, 900 to 1000, or 950 to 1000 silicon carbide segments.

In some embodiments, a thickness of the silicon carbide layer can be greater than a thickness of each of the second layer and, when present, the third layer. In some embodiments, a thickness of the silicon carbide layer can range from 1 μm to 5000 μm or any range or subrange between. For example, a thickness of the silicon carbide layer can range from 1 μm to 4000 μm, 1 μm to 3000 μm, 1 μm to 2000 μm, 1 μm to 1000 μm, 1 μm to 900 μm, 1 μm to 800 μm, 1 μm to 700 μm, 1 μm to 600 μm, 1 μm to 500 μm, 10 μm to 500 μm, 20 μm to 500 μm, 30 μm to 500 μm, 40 μm to 500 μm, 50 μm to 500 μm, 100 μm to 500 μm, 100 μm to 700 μm, 100 μm to 800 μm, 100 μm to 900 μm, or 100 μm to 1000 μm.

In some embodiments, a surface roughness average (Ra) of at least one surface of the silicon carbide layer is 0.1 nm to 100 nm, or any range or subrange between 0.1 nm and 100 nm. For example, in some embodiments, the surface roughness average of at least one surface of the silicon carbide is 0.1 nm to 90 nm, 0.1 nm to 80 nm, 0.1 nm to 70 nm, 0.1 nm to 60 nm, 0.1 nm to 50 nm, 0.1 nm to 40 nm, 0.1 nm to 30 nm, 0.1 nm to 20 nm, 0.1 nm to 10 nm, 0.1 nm to 1 nm, 10 nm to 100 nm, 20 nm to 100 nm, 30 nm to 100 nm, 40 nm to 100 nm, 50 nm to 100 nm, 60 nm to 100 nm, 70 nm to 100 nm, 80 nm to 100 nm, or 90 nm to 100 nm.

Each of the second layer and the third layer, when present, which together with the thermal interface layer form part of the thermal interface component, may independently comprise a silicon wafer or film, a silicon-on-insulator (SOI) wafer or film, a silicon carbide wafer or film, an aluminum nitride wafer or film, a gallium nitride wafer or film, a boron nitride wafer or film, or a diamond wafer or film. In some embodiments, the second layer and the third layer, when present, can be the same. For example, in one embodiment, each of the second and the third layer can be a silicon wafer. In another embodiment, each of the second and third layer can be a film. In other embodiments, the third layer, when present, is different from the second layer. For example, the second layer can be a wafer and the third layer can be a film.

In some embodiments, the second layer has a diameter of 25 mm to 450 mm, or any range or subrange between 25 mm and 450 mm. For example, in some embodiments, the second layer has a diameter of 25 mm to 300 mm, 25 mm to 200 mm, 25 mm to 150 mm, 25 mm to 125 mm, 25 mm to 100 mm, 25 mm to 76 mm, 25 mm to 51 mm, 51 mm to 450 mm, 76 mm to 450 mm, 100 mm to 450 mm, 125 mm to 450 mm, 150 mm to 450 mm, 200 mm to 450 mm, 300 mm to 450 mm. In some embodiments, the second layer has a diameter of 25 mm. In some embodiments, the second layer has a diameter of 51 mm. In some embodiments, the second layer has a diameter of 76 mm. In some embodiments, the second layer has a diameter of 100 mm. In some embodiments, the second layer has a diameter of 125 mm. In some embodiments, the second layer has a diameter of 150 mm. In some embodiments, the second layer has a diameter of 200 mm. In some embodiments, the second layer has a diameter of 300 mm. In some embodiments, the second layer has a diameter of 450 mm. Although a diameter of the second layer is provided, it will be appreciated that the second layer can be provided in other forms and thus the diameter can refer to other dimensions of the second layer, such as, for example and without limitation, a length, a width, etc.

In some embodiments, the second layer has a thickness of 0.001 μm to 1000 μm, or any range or subrange between 0.001 μm and 1000 μm. In some embodiments, for example, the second layer has a thickness of 0.001 μm to 200 μm, 0.001 μm to 190 μm, 0.001 μm to 180 μm, 0.001 μm to 170 μm, 0.001 μm to 160 μm, 0.001 μm to 150 μm, 0.001 μm to 140 μm, 0.001 μm to 130 μm, 0.001 μm to 120 μm, 0.001 μm to 110 μm, 0.001 μm to 100 μm, 0.001 μm to 90 μm, 0.001 μm to 80 μm, 0.001 μm to 70 μm, 0.001 μm to 60 μm, 0.001 μm to 50 μm, 0.001 μm to 40 μm, 0.001 μm to 30 μm, 0.001 μm to 20 μm, 0.001 μm to 10 μm, 0.001 μm to 1 μm, 0.001 μm to 0.5 μm, 0.001 μm to 0.1 μm, 0.001 μm to 0.05 μm, 0.001 μm to 0.01 μm, 0.001 μm to 0.005 μm, 0.005 μm to 200 μm, 0.01 μm to 200 μm, 0.05 μm to 200 μm, 0.1 μm to 200 μm, 0.5 μm to 200 μm, 1 μm to 200 μm, 10 μm to 200 μm, 20 μm to 200 μm, 30 μm to 200 μm, 40 μm to 200 μm, 50 μm to 200 μm, 60 μm to 200 μm, 70 μm to 200 μm, 80 μm to 200 μm, 90 μm to 200 μm, 100 μm to 200 μm, 110 μm to 200 μm, 120 μm to 200 μm, 130 μm to 200 μm, 140 μm to 200 μm, 150 μm to 200 μm, 160 μm to 200 μm, 170 μm to 200 μm, 180 μm to 200 μm, or 190 μm to 200 μm. In some embodiments, the second layer has a thickness of 100 μm to 900 μm, 100 μm to 800 μm, 100 μm to 700 μm, 100 μm to 600 μm, 100 μm to 500 μm, 100 μm to 400 μm, 100 μm to 300 μm, 100 μm to 200 μm, 200 μm to 1000 μm, 300 μm to 1000 μm, 400 μm to 1000 μm, 500 μm to 1000 μm, 600 μm to 1000 μm, 700 μm to 1000 μm, 800 μm to 1000 μm, or 900 μm to 1000 μm.

In some embodiments, the third layer has a diameter of 25 mm to 450 mm, or any range or subrange between 25 mm and 450 mm. For example, in some embodiments, the third layer has a diameter of 25 mm to 300 mm, 25 mm to 200 mm, 25 mm to 150 mm, 25 mm to 125 mm, 25 mm to 100 mm, 25 mm to 76 mm, 25 mm to 51 mm, 51 mm to 450 mm, 76 mm to 450 mm, 100 mm to 450 mm, 125 mm to 450 mm, 150 mm to 450 mm, 200 mm to 450 mm, 300 mm to 450 mm. In some embodiments, the third layer has a diameter of 25 mm. In some embodiments, the third layer has a diameter of 51 mm. In some embodiments, the third layer has a diameter of 76 mm. In some embodiments, the third layer has a diameter of 100 mm. In some embodiments, the third layer has a diameter of 125 mm. In some embodiments, the third layer has a diameter of 150 mm. In some embodiments, the third layer has a diameter of 200 mm. In some embodiments, the third layer has a diameter of 300 mm. In some embodiments, the third layer has a diameter of 450 mm. In some embodiments, a diameter of the third layer is different from a diameter of the second layer. Although a diameter of the third layer is provided, it will be appreciated that the third layer can be provided in other forms and thus the diameter can refer to other dimensions of the third layer, such as, for example and without limitation, a length, a width, etc.

In some embodiments, a thickness of the third layer is different from a thickness of the second layer. In some embodiments, the third layer has a thickness of 0.001 μm to 1000 μm, or any range or subrange between 0.001 μm and 1000 μm. In some embodiments, for example, the third layer has a thickness of 0.001 μm to 200 μm, 0.001 μm to 190 μm, 0.001 μm to 180 μm, 0.001 μm to 170 μm, 0.001 μm to 160 μm, 0.001 μm to 150 μm, 0.001 μm to 140 μm, 0.001 μm to 130 μm, 0.001 μm to 120 μm, 0.001 μm to 110 μm, 0.001 μm to 100 μm, 0.001 μm to 90 μm, 0.001 μm to 80 μm, 0.001 μm to 70 μm, 0.001 μm to 60 μm, 0.001 μm to 50 μm, 0.001 μm to 40 μm, 0.001 μm to 30 μm, 0.001 μm to 20 μm, 0.001 μm to 10 μm, 0.001 μm to 1 μm, 0.001 μm to 0.5 μm, 0.001 μm to 0.1 μm, 0.001 μm to 0.05 μm, 0.001 μm to 0.01 μm, 0.001 μm to 0.005 μm, 0.005 μm to 200 μm, 0.01 μm to 200 μm, 0.05 μm to 200 μm, 0.1 μm to 200 μm, 0.5 μm to 200 μm, 1 μm to 200 μm, 10 μm to 200 μm, 20 μm to 200 μm, 30 μm to 200 μm, 40 μm to 200 μm, 50 μm to 200 μm, 60 μm to 200 μm, 70 μm to 200 μm, 80 μm to 200 μm, 90 μm to 200 μm, 100 μm to 200 μm, 110 μm to 200 μm, 120 μm to 200 μm, 130 μm to 200 μm, 140 μm to 200 μm, 150 μm to 200 μm, 160 μm to 200 μm, 170 μm to 200 μm, 180 μm to 200 μm, or 190 μm to 200 μm. In some embodiments, the third layer has a thickness of 100 μm to 900 μm, 100 μm to 800 μm, 100 μm to 700 μm, 100 μm to 600 μm, 100 μm to 500 μm, 100 μm to 400 μm, 100 μm to 300 μm, 100 μm to 200 μm, 200 μm to 1000 μm, 300 μm to 1000 μm, 400 μm to 1000 μm, 500 μm to 1000 μm, 600 μm to 1000 μm, 700 μm to 1000 μm, 800 μm to 1000 μm, or 900 μm to 1000 μm.

The diamond layer or silicon carbide layer, whether provided as a continuous layer in the form of a wafer or substrate, or as a layer comprising a plurality of segments as described herein, may be directly or indirectly bonded to at least one of the second layer, the third layer, or both to form a thermal interface component for integration into a semiconductor device. The diamond layer or the silicon carbide layer can be directly bonded to the second layer and/or the third layer. The direct bond may comprise a chemical bond, such as a covalent bond. In other embodiments, the diamond layer or silicon carbide layer can be indirectly bonded to the second layer and/or the third layer via an intervening layer disposed between the diamond layer or silicon carbide layer and the silicon layer. The intervening layer can include a silicon layer, silicon carbide layer, a silicide layer, an amorphous carbon layer, or a combination thereof.

In some embodiments, direct bonding of the first layer (e.g., a diamond layer or a silicon carbide layer) to a silicon layer is facilitated by preparing at least one bonding surface to have low roughness and high flatness. Surface roughness can reduce true contact area and promote asperity-induced voiding at an interface, which can increase thermal boundary resistance and reduce bond strength. Accordingly, in some embodiments, at least one surface of the diamond layer and/or the silicon carbide layer is planarized and polished prior to bonding to reduce roughness and improve bonding uniformity.

In some embodiments, direct covalent bonding between the diamond layer or silicon carbide layer and a silicon layer is achieved using low-temperature surface-activated bonding (SAB). In such embodiments, at least one surface of the diamond layer and at least one surface of the silicon layer are subjected to a surface activation treatment that removes surface contamination and creates chemically active surface states. When the activated surfaces are brought into contact, direct bonding can occur without an intervening adhesive layer and without exposure to high bonding temperatures. In some embodiments, the resulting bond comprises silicon-carbon (Si—C) covalent bonds formed across the interface.

In some embodiments, to facilitate bonding, the diamond layer or silicon carbide layer is polished using a chemical-mechanical polishing (CMP) process employing a slurry that includes a liquid carrier, abrasive particles, and chemical additives that promote controlled removal of diamond or silicon carbide material. In certain embodiments, an oxidizing agent and pH control (acidic or basic) are used to enhance removal and reduce subsurface damage, thereby producing a smoother surface suitable for subsequent bonding. The CMP can be used to produce a surface roughness (Ra) within a range suitable for direct bonding, including the surface roughness ranges described herein. Lower surface roughness can increase the fraction of real contact area achieved during bonding, reduce trapped interfacial voids, and thereby reduce thermal boundary resistance and improve bond reliability during thermal cycling. Additionally, CMP processes can be used to control wafer-scale flatness and local thickness uniformity. For example, control of total thickness variation (TTV) and/or local thickness variation (LTV) can improve bonding uniformity across the bonding interface during formation of the thermal interface component or semiconductor packaging stack by promoting uniform contact pressure and reducing regions susceptible to void formation or incomplete bonding.

In some embodiments, the thermal interface component has a total thickness variation (TTV) of 0.1 μm to 10 μm across the thermal interface component parallel to a surface of the thermal interface component, or any range or subrange between 0.1 μm and 10 μm. For example, in some embodiments, the thermal interface component has a TTV of 0.1 μm to 9 μm, 0.1 μm to 8 μm, 0.1 μm to 7 μm, 0.1 μm to 6 μm, 0.1 μm to 5 μm, 0.1 μm to 4 μm, 0.1 μm to 3 μm, 0.1 μm to 2 μm, 0.1 μm to 1 μm, 0.1 μm to 0.5 μm, 0.5 μm to 10 μm, 1 μm to 10 μm, 2 μm to 10 μm, 3 μm to 10 μm, 4 μm to 10 μm, 5 μm to 10 μm, 6 μm to 10 μm, 7 μm to 10 μm, 8 μm to 10 μm, or 9 μm to 10 μm. In some embodiments, the thermal interface component has a TTV of 5 μm or less. In some embodiments, the thermal interface component has a TTV of 3 μm or less. In some embodiments, the thermal interface component has a TTV of 1 μm or less. As used herein, TTV refers to the difference between the maximum thickness and the minimum thickness of the thermal interface component measured across the full extent of the component parallel to a major surface thereof.

In some embodiments, the thermal interface component has a local thickness variation (LTV) of 0.01 μm to 5 μm over a gauge length of 10 mm, or any range or subrange between 0.01 μm and 5 μm. For example, in some embodiments, the thermal interface component has an LTV of 0.01 μm to 4.5 μm, 0.01 μm to 4 μm, 0.01 μm to 3.5 μm, 0.01 μm to 3 μm, 0.01 μm to 2.5 μm, 0.01 μm to 2 μm, 0.01 μm to 1.5 μm, 0.01 μm to 1 μm, 0.01 μm to 0.5 μm, 0.01 μm to 0.1 μm, 0.01 μm to 0.05 μm, 0.05 μm to 5 μm, 0.1 μm to 5 μm, 0.5 μm to 5 μm, 1 μm to 5 μm, 1.5 μm to 5 μm, 2 μm to 5 μm, 2.5 μm to 5 μm, 3 μm to 5 μm, 3.5 μm to 5 μm, 4 μm to 5 μm, or 4.5 μm to 5 μm. In some embodiments, the thermal interface component has an LTV of 1 μm or less over a 10 mm gauge length. In some embodiments, the thermal interface component has an LTV of 0.5 μm or less over a 10 mm gauge length. In some embodiments, the thermal interface component has an LTV of 0.1 μm or less over a 10 mm gauge length. As used herein, LTV refers to the maximum thickness variation of the thermal interface component measured within a localized region defined by the stated gauge length.

TTV and LTV can be controlled during fabrication by, for example, chemical mechanical polishing of the thermal interface component or one or more individual layers thereof prior to or after bonding, as described herein. Lower TTV and LTV values can promote more uniform contact pressure during bonding, reduce interfacial void density, and improve thermal and mechanical uniformity of the bonded interface across the full area of the thermal interface component.

In some embodiments, when the thermal interface component is heated to a temperature in a range of 25 °C to 500 °C, or any range or subrange between 25 °C and 500 °C, and subsequently tested according to ASTM C1624, an adhesion energy required to separate the thermal interface layer from the second layer (or the third layer) is 0.1 J/m² to 4 J/m², or any range or subrange between 0.1 J/m² and 4 J/m². For example, in some embodiments, the adhesion energy required to separate the diamond layer from the second layer (or the third layer) is 0.1 J/m² to 4 J/m², 0.1 J/m² to 3.8 J/m², 0.1 J/m² to 3.6 J/m², 0.1 J/m² to 3.5 J/m², 0.1 J/m² to 3.4 J/m², 0.1 J/m² to 3.2 J/m², 0.1 J/m² to 3 J/m², 0.1 J/m² to 2.8 J/m², 0.1 J/m² to 2.6 J/m², 0.1 J/m² to 2.5 J/m², 0.1 J/m² to 2.4 J/m², 0.1 J/m² to 2.2 J/m², 0.1 J/m² to 2 J/m², 0.1 J/m² to 1.8 J/m², 0.1 J/m² to 1.6 J/m², 0.1 J/m² to 1.5 J/m², 0.1 J/m² to 1.4 J/m², 0.1 J/m² to 1.2 J/m², 0.1 J/m² to 1 J/m², 0.1 J/m² to 0.8 J/m², 0.1 J/m² to 0.6 J/m², 0.1 J/m² to 0.5 J/m², 0.1 J/m² to 0.4 J/m², or 0.1 J/m² to 0.2 J/m². In some embodiments, the adhesion energy required to separate the diamond layer or the silicon carbide layer from the second layer (or the third layer) is 0.5 J/m² to 2 J/m².

In some embodiments, before testing the thermal interface component according to ASTM C1624, the thermal interface component is heated to a temperature of 25 °C to 500 °C, or any range or subrange between 25 °C and 500 °C For example, in some embodiments, before testing the thermal interface component according to ASTM C1624, the thermal interface component is heated to a temperature of 25 °C to 500 °C, 25 °C to 480 °C, 25 °C to 460 °C, 25 °C to 440 °C, 25 °C to 420 °C, 25 °C to 400 °C, 25 °C to 380 °C, 25 °C to 360 °C, 25 °C to 340 °C, 25 °C to 320 °C, 25 °C to 300 °C, 25 °C to 280 °C, 25 °C to 260 °C, 25 °C to 240 °C, 25 °C to 220 °C, 25 °C to 200 °C, 25 °C to 180 °C, 25 °C to 160 °C, 25 °C to 140 °C, 25 °C to 120 °C, 25 °C to 100 °C, 25 °C to 80 °C, 25 °C to 60 °C, 25 °C to 40 °C, 40 °C to 500 °C, 60 °C to 500 °C, 80 °C to 500 °C, 100 °C to 500 °C, 120 °C to 500 °C, 140 °C to 500 °C, 160 °C to 500 °C, 180 °C to 500 °C, 200 °C to 500 °C, 220 °C to 500 °C, 240 °C to 500 °C, 260 °C to 500 °C, 280 °C to 500 °C, 300 °C to 500 °C, 320 °C to 500 °C, 340 °C to 500 °C, 360 °C to 500 °C, 380 °C to 500 °C, 400 °C to 500 °C, 420 °C to 500 °C, 440 °C to 500 °C, 460 °C to 500 °C, or 480 °C to 500 °C. In some embodiments, before testing the thermal interface component according to ASTM C1624, the thermal interface component is heated to a temperature of 200 °C

In some embodiments, when measured at a temperature in a range of 25 °C to 500 °C, or any range or subrange between 25 °C and 500 °C, according to ASTM E228, a coefficient of thermal expansion of the thermal interface layer is at least 50% less than a coefficient of thermal expansion of the second layer (or the third layer). For example, in some embodiments, the coefficient of thermal expansion of the diamond layer is 1% to 50%, 1% to 45%, 1% to 40%, 1% to 35%, 1% to 30%, 1% to 25%, 1% to 20%, 1% to 15%, 1% to 10%, 1% to 5%, 5% to 50%, 10% to 50%, 15% to 50%, 20% to 50%, 25% to 50%, 30% to 50%, 35% to 50%, 40% to 50%, or 45% to 50% less than the coefficient of thermal expansion of the second layer (or the third layer).

In some embodiments, when measured at a temperature in a range of 25 °C to 500 °C, or any range or subrange between 25 °C and 500 °C, according to ASTM E228, a coefficient of thermal expansion of the thermal interface layer is 1×10⁻⁶ K⁻¹ to 3×10⁻⁶ K⁻¹, as measured according to ASTM E228, or any range or subrange between 1×10⁻⁶ K⁻¹ and 3×10⁻⁶ K⁻¹. For example, in some embodiments, the coefficient of thermal expansion of the diamond layer or silicon carbide layer ranges from 1×10⁻⁶ K⁻¹ to 3×10⁻⁶ K⁻¹, 1×10⁻⁶ K⁻¹ to 2.8×10⁻⁶ K⁻¹, 1×10⁻⁶ K⁻¹ to 2.6×10⁻⁶ K⁻¹, 1×10⁻⁶ K⁻¹ to 2.4×10⁻⁶ K⁻¹, 1×10⁻⁶ K⁻¹ to 2.2×10⁻⁶ K⁻¹, 1×10⁻⁶ K⁻¹ to 2×10⁻⁶ K⁻¹, 1×10⁻⁶ K⁻¹ to 1.8×10⁻⁶ K⁻¹, 1×10⁻⁶ K⁻¹ to 1.6×10⁻⁶ K⁻¹, 1×10⁻⁶ K⁻¹ to 1.4×10⁻⁶ K⁻¹, 1×10⁻⁶ K⁻¹ to 1.2×10⁻⁶ K⁻¹, 1.2×10⁻⁶ K⁻¹ to 3×10⁻⁶ K⁻¹, 1.4×10⁻⁶ K⁻¹ to 3×10⁻⁶ K⁻¹, 1.6×10⁻⁶ K⁻¹ to 3×10⁻⁶ K⁻¹, 1.8×10⁻⁶ K⁻¹ to 3×10⁻⁶ K⁻¹, 2×10⁻⁶ K⁻¹ to 3×10⁻⁶ K⁻¹, 2.2×10⁻⁶ K⁻¹ to 3×10⁻⁶ K⁻¹, 2.4×10⁻⁶ K⁻¹ to 3×10⁻⁶ K⁻¹, 2.6×10⁻⁶ K⁻¹ to 3×10⁻⁶ K⁻¹, or 2.8×10⁻⁶ K⁻¹ to 3×10⁻⁶ K⁻¹ as measured according to ASTM E228. In some embodiments, the coefficient of thermal expansion of the diamond layer or silicon carbide layer ranges from 1.5×10⁻⁶ K⁻¹ to 2.5×10⁻⁶ K⁻¹, as measured according to ASTM E228.

In some embodiments, the coefficient of thermal expansion is tested at a temperature in a range of 25 °C to 500 °C, or any range or subrange between 25 °C and 500 °C. For example, in some embodiments, the coefficient of thermal expansion is tested at a temperature in a range of 25 °C to 500 °C, 25 °C to 480 °C, 25 °C to 460 °C, 25 °C to 440 °C, 25 °C to 420 °C, 25 °C to 400 °C, 25 °C to 380 °C, 25 °C to 360 °C, 25 °C to 340 °C, 25 °C to 320 °C, 25 °C to 300 °C, 25 °C to 280 °C, 25 °C to 260 °C, 25 °C to 240 °C, 25 °C to 220 °C, 25 °C to 200 °C, 25 °C to 180 °C, 25 °C to 160 °C, 25 °C to 140 °C, 25 °C to 120 °C, 25 °C to 100 °C, 25 °C to 80 °C, 25 °C to 60 °C, 25 °C to 40 °C, 40 °C to 500 °C, 60 °C to 500 °C, 80 °C to 500 °C, 100 °C to 500 °C, 120 °C to 500 °C, 140 °C to 500 °C, 160 °C to 500 °C, 180 °C to 500 °C, 200 °C to 500 °C, 220 °C to 500 °C, 240 °C to 500 °C, 260 °C to 500 °C, 280 °C to 500 °C, 300 °C to 500 °C, 320 °C to 500 °C, 340 °C to 500 °C, 360 °C to 500 °C, 380 °C to 500 °C, 400 °C to 500 °C, 420 °C to 500 °C, 440 °C to 500 °C, 460 °C to 500 °C, or 480 °C to 500 °C.

In some embodiments, the thermal interface component comprises at least one intervening layer. In some cases, the intervening layer can be a metal layer.

In some embodiments, the at least one metal layer comprises an elemental metal, a metal alloy, or any combination thereof. In some embodiments, the metal layer comprises at least one of titanium, cobalt, gold, or any combination thereof. It will be appreciated that the metal layer can comprise other metals, including, for example and without limitation, at least one of an alkali metal, an alkaline earth metal, a transition metal, a post-transition metal, a lanthanoid, an actinoid, or any combination thereof, without departing from the scope of this disclosure.

In some embodiments, the at least one metal layer can be deposited by a deposition process (e.g., a vapor deposition process). In some embodiments, the at least one metal layer can be deposited via an atomic layer deposition (ALD) process. In other embodiments, the at least one metal layer can be deposited via a chemical vapor deposition (CVD) process. It will be appreciated that the at least one metal layer can be formed by one or more other deposition processes. Non-limiting examples of deposition processes include, for example and without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

In some embodiments, the at least one metal layer can be located between the second layer and the diamond layer or the silicon carbide layer. In some embodiments, the at least one metal layer directly contacts the second layer. In some embodiments, the at least one metal layer is directly bonded to the second layer. In some embodiments, the at least one metal layer is directly bonded to the second layer via a chemical bond. For example, in some embodiments, the at least one metal layer is directly bonded to the second layer via a covalent bond. In some embodiments, the at least one metal layer is melt-or heat-bonded to the second layer. In some embodiments, the at least one metal layer is bonded to the second layer via an intervening layer. For example, in some embodiments, an intervening layer is located between the at least one metal layer and the second layer. The intervening layer can include a silicon carbide layer, a silicide layer, an amorphous carbon layer, or a combination thereof.

In some embodiments, the at least one metal layer can be located between the second layer or the third layer and the thermal interface layer. In some embodiments, the at least one metal layer directly contacts the second layer or the third layer. In some embodiments, the at least one metal layer is directly bonded to the second layer or the third layer. In some embodiments, the at least one metal layer is directly bonded to the second or the third layer via a chemical bond. For example, in some embodiments, the at least one metal layer is directly bonded to the second or the third layer via a covalent bond. In some embodiments, the at least one metal layer is melt-or heat-bonded to the third layer. In some embodiments, the at least one metal layer is bonded to the second or third layer via another intervening layer. For example, in some embodiments, an intervening layer is located between the at least one metal layer and the second or third layer. The intervening layer can include a silicon carbide layer, a silicide layer, an amorphous carbon layer, or a combination thereof.

In some embodiments, the at least one metal layer is located between the diamond layer and at least one of the second layer, the third layer, or any combination thereof. In some embodiments, the at least one metal layer is directly bonded to the diamond layer and to at least one of the second layer, the third layer, or any combination thereof. In some embodiments, the at least one metal layer is directly bonded to the diamond layer, the second layer, the third layer, or any combination thereof. In other embodiments, the at least one metal layer is bonded to the diamond layer, the second layer, the third layer, or any combination thereof via one or more intervening layers. The bond may be a chemical bond such as, for example, a covalent bond. The intervening layer can include a silicon carbide layer, a silicide layer, an amorphous carbon layer, or a combination thereof.

In some embodiments, the at least one metal layer is located between the silicon carbide layer and at least one of the second layer, the third layer, or any combination thereof. In some embodiments, the at least one metal layer is bonded to the silicon carbide layer, the second layer, the third layer, or any combination thereof. In some embodiments, the at least one metal layer is bonded to the silicon carbide layer, the second layer, the third layer, or any combination thereof via one or more intervening layers. The bond may be a chemical bond such as, for example, a covalent bond. The intervening layer can include a silicon carbide layer, a silicide layer, an amorphous carbon layer, or a combination thereof.

According to various embodiments, the at least one metal layer has a thickness of 0.1 nm to 100 nm, or any range or subrange between 0.1 nm and 100 nm. For example, in some embodiments, the at least one metal layer has a thickness of 0.1 nm to 90 nm, 0.1 nm to 80 nm, 0.1 nm to 70 nm, 0.1 nm to 60 nm, 0.1 nm to 50 nm, 0.1 nm to 40 nm, 0.1 nm to 30 nm, 0.1 nm to 20 nm, 0.1 nm to 10 nm, 10 nm to 100 nm, 20 nm to 100 nm, 30 nm to 100 nm, 40 nm to 100 nm, 50 nm to 100 nm, 60 nm to 100 nm, 70 nm to 100 nm, 80 nm to 100 nm, or 90 nm to 100 nm.

In some embodiments, when the thermal interface component is heated to a temperature in a range of 25 °C to 500 °C, or any range or subrange between 25 °C and 500 °C, and subsequently tested according to ASTM C1624, an adhesion energy required to separate the at least one intervening metal layer from the second layer (or the third layer) is 0.1 J/m² to 4 J/m², or any range or subrange between 0.1 J/m² and 4 J/m². For example, in some embodiments, the adhesion energy required to separate a metal layer from the substrate 210 is 0.1 J/m² to 4 J/m², 0.1 J/m² to 3.8 J/m², 0.1 J/m² to 3.6 J/m², 0.1 J/m² to 3.5 J/m², 0.1 J/m² to 3.4 J/m², 0.1 J/m² to 3.2 J/m², 0.1 J/m² to 3 J/m², 0.1 J/m² to 2.8 J/m², 0.1 J/m² to 2.6 J/m², 0.1 J/m² to 2.5 J/m², 0.1 J/m² to 2.4 J/m², 0.1 J/m² to 2.2 J/m², 0.1 J/m² to 2 J/m², 0.1 J/m² to 1.8 J/m², 0.1 J/m² to 1.6 J/m², 0.1 J/m² to 1.5 J/m², 0.1 J/m² to 1.4 J/m², 0.1 J/m² to 1.2 J/m², 0.1 J/m² to 1 J/m², 0.1 J/m² to 0.8 J/m², 0.1 J/m² to 0.6 J/m², 0.1 J/m² to 0.5 J/m², 0.1 J/m² to 0.4 J/m², or 0.1 J/m² to 0.2 J/m². In some embodiments, the adhesion energy required to separate the at least one metal layer from the second layer (or the third layer) is 0.5 J/m² to 2 J/m².

In some embodiments, when the thermal interface component is heated to a temperature in a range of 25 °C to 500 °C, or any range or subrange between 25 °C and 500 °C, and subsequently tested according to ASTM C1624, an adhesion energy required to separate the thermal interface layer from the at least one metal layer is 0.1 J/m² to 4 J/m², or any range or subrange between 0.1 J/m² and 4 J/m². For example, in some embodiments, the adhesion energy required to separate the diamond layer from the at least one metal layer is 0.1 J/m² to 4 J/m², 0.1 J/m² to 3.8 J/m², 0.1 J/m² to 3.6 J/m², 0.1 J/m² to 3.5 J/m², 0.1 J/m² to 3.4 J/m², 0.1 J/m² to 3.2 J/m², 0.1 J/m² to 3 J/m², 0.1 J/m² to 2.8 J/m², 0.1 J/m² to 2.6 J/m², 0.1 J/m² to 2.5 J/m², 0.1 J/m² to 2.4 J/m², 0.1 J/m² to 2.2 J/m², 0.1 J/m² to 2 J/m², 0.1 J/m² to 1.8 J/m², 0.1 J/m² to 1.6 J/m², 0.1 J/m² to 1.5 J/m², 0.1 J/m² to 1.4 J/m², 0.1 J/m² to 1.2 J/m², 0.1 J/m² to 1 J/m², 0.1 J/m² to 0.8 J/m², 0.1 J/m² to 0.6 J/m², 0.1 J/m² to 0.5 J/m², 0.1 J/m² to 0.4 J/m², or 0.1 J/m² to 0.2 J/m². In some embodiments, the adhesion energy required to separate the thermal interface layer from the at least one metal layer is 0.5 J/m² to 2 J/m².

In some embodiments, before testing the thermal interface component according to ASTM C1624, the thermal interface component is heated to a temperature in a range of 25 °C to 500 °C, or any range or subrange between 25 °C and 500 °C For example, in some embodiments, before testing the thermal interface component according to ASTM C1624, the thermal interface component is heated to a temperature of 25 °C to 500 °C, 25 °C to 480 °C, 25 °C to 460 °C, 25 °C to 440 °C, 25 °C to 420 °C, 25 °C to 400 °C, 25 °C to 380 °C, 25 °C to 360 °C, 25 °C to 340 °C, 25 °C to 320 °C, 25 °C to 300 °C, 25 °C to 280 °C, 25 °C to 260 °C, 25 °C to 240 °C, 25 °C to 220 °C, 25 °C to 200 °C, 25 °C to 180 °C, 25 °C to 160 °C, 25 °C to 140 °C, 25 °C to 120 °C, 25 °C to 100 °C, 25 °C to 80 °C, 25 °C to 60 °C, 25 °C to 40 °C, 40 °C to 500 °C, 60 °C to 500 °C, 80 °C to 500 °C, 100 °C to 500 °C, 120 °C to 500 °C, 140 °C to 500 °C, 160 °C to 500 °C, 180 °C to 500 °C, 200 °C to 500 °C, 220 °C to 500 °C, 240 °C to 500 °C, 260 °C to 500 °C, 280 °C to 500 °C, 300 °C to 500 °C, 320 °C to 500 °C, 340 °C to 500 °C, 360 °C to 500 °C, 380 °C to 500 °C, 400 °C to 500 °C, 420 °C to 500 °C, 440 °C to 500 °C, 460 °C to 500 °C, or 480 °C to 500 °C. In some embodiments, before testing the thermal interface component according to ASTM C1624, the thermal interface component is heated to a temperature of 200 °C.

In some embodiments, a coefficient of thermal expansion of the at least one metal layer is greater than each of a coefficient of thermal expansion of the second layer (or the third layer) and a coefficient of thermal expansion of the thermal interface layer. For example, in some embodiments, the coefficient of thermal expansion of the at least one metal layer is 10% to 200%, or any range or subrange between 10% and 200%, greater than the coefficient of thermal expansion of the second layer (or the third layer).

In some embodiments, the coefficient of thermal expansion of the at least one metal layer is 10% to 200%, 10% to 190%, 10% to 180%, 10% to 170%, 10% to 160%, 10% to 150%, 10% to 140%, 10% to 130%, 10% to 120%, 10% to 110%, 10% to 100%, 10% to 90%, 10% to 80%, 10% to 70%, 10% to 60%, 10% to 50%, 10% to 40%, 10% to 30%, 10% to 20%, 20% to 200%, 30% to 200%, 40% to 200%, 50% to 200%, 60% to 200%, 70% to 200%, 80% to 200%, 90% to 200%, 100% to 200%, 110% to 200%, 120% to 200%, 130% to 200%, 140% to 200%, 150% to 200%, 160% to 200%, 170% to 200%, 180% to 200%, or 190% to 200% greater than the coefficient of thermal expansion of the second layer (or the third layer).

In some embodiments, the coefficient of thermal expansion of the at least one metal layer is 400% to 1000%, or any range or subrange between 400% and 1000%, greater than the coefficient of thermal expansion of the diamond layer or the silicon carbide layer. In some embodiments, the coefficient of thermal expansion of the at least one metal layer is 400% to 1000%, 400% to 950%, 400% to 900%, 400% to 850%, 400% to 800%, 400% to 750%, 400% to 700%, 400% to 650%, 400% to 600%, 400% to 550%, 400% to 500%, 450% to 1000%, 500% to 1000%, 550% to 1000%, 600% to 1000%, 650% to 1000%, 700% to 1000%, 750% to 1000%, 800% to 1000%, 850% to 1000%, 900% to 1000%, or 950% to 1000% greater than the coefficient of thermal expansion of the diamond layer or silicon carbide layer.

In some embodiments, the coefficient of thermal expansion of each of the second layer (or the third layer) and the at least one metal layer is greater than 3×10⁻⁶ K⁻¹, as measured according to ASTM E228. For example, in some embodiments, the coefficient of thermal expansion of each of the non-diamond or non-silicon carbide layers (e.g., at least one of the second layer, the third layer, the at least one metal layer, or any combination thereof) is independently 3.1×10⁻⁶ K⁻¹ to 9×10⁻⁶ K⁻¹, as measured according to ASTM E228, or any range or subrange between 3.1×10⁻⁶ K⁻¹ and 9×10⁻⁶ K⁻¹. In some embodiments, the coefficient of thermal expansion of each of the non-diamond or non-silicon carbide layers is independently 3.1×10⁻⁶ K⁻¹ to 9×10⁻⁶ K⁻¹, 3.1×10⁻⁶ K⁻¹ to 8×10⁻⁶ K⁻¹, 3.1×10⁻⁶ K⁻¹ to 7×10⁻⁶ K⁻¹, 3.1×10⁻⁶ K⁻¹ to 6×10⁻⁶ K⁻¹, 3.1×10⁻⁶ K⁻¹ to 5×10⁻⁶ K⁻¹, 3.1×10⁻⁶ K⁻¹ to 4×10⁻⁶ K⁻¹, 4×10⁻⁶ K⁻¹ to 9×10⁻⁶ K⁻¹, 5×10⁻⁶ K⁻¹ to 9×10⁻⁶ K⁻¹, 6×10⁻⁶ K⁻¹ to 9×10⁻⁶ K⁻¹, 7×10⁻⁶ K⁻¹ to 9×10⁻⁶ K⁻¹, or 8×10⁻⁶ K⁻¹ to 9×10⁻⁶ K⁻¹ as measured according to ASTM E228. In some embodiments, the coefficient of thermal expansion of the at least one metal layer is independently 4.5×10⁻⁶ K⁻¹ to 9×10⁻⁶ K⁻¹. In some embodiments, the coefficient of thermal expansion of the second layer (or the third layer) is independently 4×10⁻⁶ K⁻¹.

In some embodiments, the coefficient of thermal expansion is tested at a temperature in a range of 25 °C to 500 °C, or any range or subrange between 25 °C and 500 °C. For example, in some embodiments, the coefficient of thermal expansion is tested at a temperature in a range of 25 °C to 500 °C, 25 °C to 480 °C, 25 °C to 460 °C, 25 °C to 440 °C, 25 °C to 420 °C, 25 °C to 400 °C, 25 °C to 380 °C, 25 °C to 360 °C, 25 °C to 340 °C, 25 °C to 320 °C, 25 °C to 300 °C, 25 °C to 280 °C, 25 °C to 260 °C, 25 °C to 240 °C, 25 °C to 220 °C, 25 °C to 200 °C, 25 °C to 180 °C, 25 °C to 160 °C, 25 °C to 140 °C, 25 °C to 120 °C, 25 °C to 100 °C, 25 °C to 80 °C, 25 °C to 60 °C, 25 °C to 40 °C, 40 °C to 500 °C, 60 °C to 500 °C, 80 °C to 500 °C, 100 °C to 500 °C, 120 °C to 500 °C, 140 °C to 500 °C, 160 °C to 500 °C, 180 °C to 500 °C, 200 °C to 500 °C, 220 °C to 500 °C, 240 °C to 500 °C, 260 °C to 500 °C, 280 °C to 500 °C, 300 °C to 500 °C, 320 °C to 500 °C, 340 °C to 500 °C, 360 °C to 500 °C, 380 °C to 500 °C, 400 °C to 500 °C, 420 °C to 500 °C, 440 °C to 500 °C, 460 °C to 500 °C, or 480 °C to 500 °C.

In some embodiments, a thermal interface component as described herein is integrated into a semiconductor device comprising a semiconductor packaging stack. The semiconductor packaging stack may include a plurality of semiconductor dies arranged in a stacked configuration, a laterally distributed configuration, or a combination thereof, along with one or more packaging layers disposed between, above, or below the semiconductor dies. The stacked thermal interface component may be disposed within the semiconductor packaging stack to provide thermal coupling between one or more semiconductor dies and adjacent packaging layers, substrates, interposers, heat spreaders, or other structural elements of the semiconductor device.

In some embodiments, the semiconductor packaging stack includes at least one logic die and one or more memory dies. The logic die may comprise, for example, a processor die, controller die, or accelerator die, and the one or more memory dies may comprise volatile or non-volatile memory devices. In such embodiments, the logic die and the one or more memory dies may be stacked with one or more polymer dielectric layers forming part of the semiconductor packaging stack, such as dielectric layers used for redistribution, interconnect routing, electrical isolation, or mechanical support. The stacked thermal interface component may be disposed between at least one of the logic die or the memory dies and an adjacent layer of the semiconductor packaging stack to facilitate heat transfer from the logic die and/or the memory dies.

In some embodiments, the semiconductor packaging stack comprises a graphics processing unit (GPU) die and one or more high-bandwidth memory (HBM) dies arranged in a stacked or adjacent configuration. In such embodiments, the semiconductor packaging stack may further include polymer dielectric redistribution layers configured to route electrical signals between the GPU die, the HBM dies, and other components of the semiconductor device. The stacked thermal interface component may be thermally coupled to at least one of the GPU die or the one or more HBM dies to conduct heat away from the GPU die and/or the HBM dies and toward an adjacent layer of the semiconductor packaging stack, such as a heat spreader, interposer, substrate, or packaging layer.

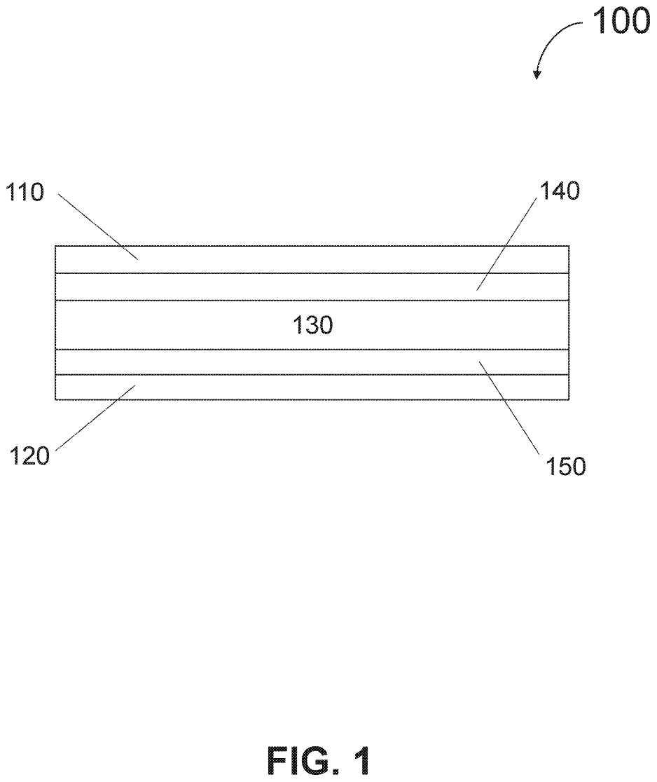

FIG. 1 is a schematic diagram of a cross-sectional view of a thermal interface component 100, according to some embodiments. As shown in FIG. 1, the thermal interface component 100 includes a first layer 130 disposed between a second layer 110 and a third layer 120. The first layer 130 can comprise any one of thermal interface materials as described herein and thus is a thermal interface layer. In some embodiments, the first layer 130 can include diamond and/or silicon carbide. A first intervening layer 140 is disposed between the second layer 110 and the first layer 130, and a second intervening layer 150 is disposed between the third layer 120 and the first layer 130. The intervening layers 140, 150 may comprise metal layers or other bonding layers, and adjacent layers may be bonded directly or indirectly as described herein.

In further reference to FIG. 1, in some embodiments, the first layer 130 is located between the first intervening layer 140 and the second intervening layer 150, the first intervening layer 140 is located between the second layer 110 and the first layer 130, and the second intervening layer 150 is located between the third layer 120 and the first layer 130. In the illustrated embodiment, the thermal interface component 100 does not comprise any layers other than the layers depicted in FIG. 1. Accordingly, adjacent layers and structures shown in FIG. 1 can be directly bonded to each other (e.g., via a covalent bond, such as, for example and without limitation, silicon carbide bonds and metal carbide bonds), or at least in direct contact with each other.

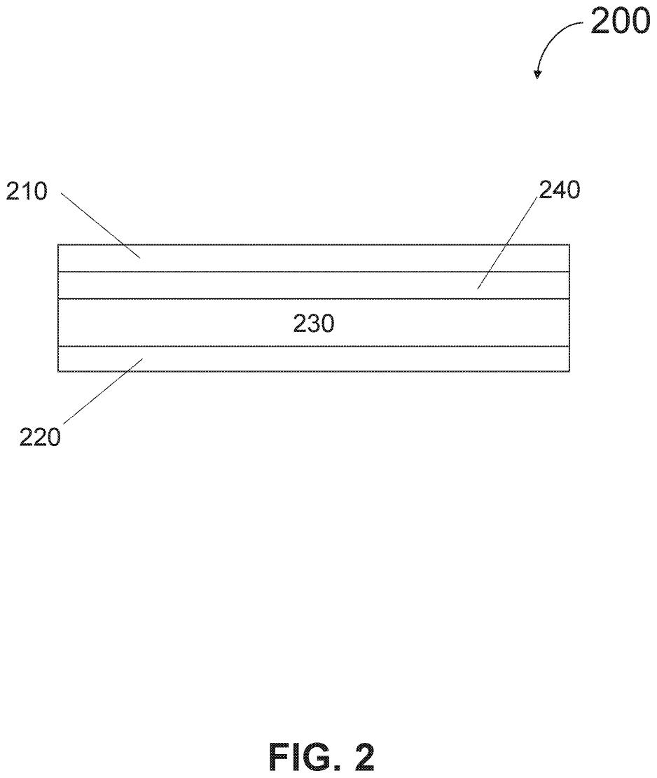

FIG. 2 is a schematic diagram of a cross-sectional view of a thermal interface component 200, according to some embodiments. As shown in FIG. 2, the thermal interface component 200 includes a first layer 230 disposed between a second layer 210 and a third layer 220. An intervening layer 240 is disposed between the second layer 210 and the first layer 230, while the first layer 230 is directly bonded to the third layer 220. This embodiment illustrates asymmetric bonding in which one interface includes an intervening layer and the opposing interface is directly bonded.

In further reference to FIG. 2, in some embodiments, the first layer 230 is located between the first metal layer 240 and the third layer 220, and the first intervening layer 240 is located between the second layer 210 and the first layer 230. In the illustrated embodiment, the thermal interface component 200 does not comprise any layers other than the layers depicted in FIG. 2. Accordingly, adjacent layers and structures shown in FIG. 2 can be directly bonded to each other (e.g., via a covalent bond, such as, for example and without limitation, silicon carbide bonds and metal carbide bonds), or at least in direct contact with each other.

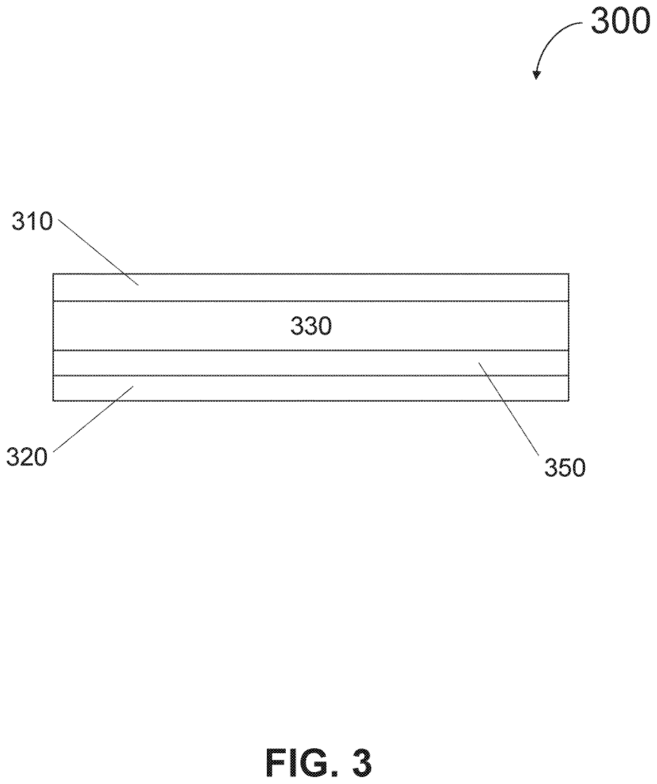

FIG. 3 is a schematic diagram of a cross-sectional view of a thermal interface component 300, according to some embodiments. As shown in FIG. 3, the thermal interface component 300 includes a first layer 330 disposed between a second layer 310 and a third layer 320. An intervening layer 350 is disposed between the first layer 330 and the third layer 320, while the first layer 330 is directly bonded to the second layer 310. This embodiment illustrates an alternative placement of an intervening layer relative to the diamond layer.

In further reference to FIG. 3, in some embodiments, the first layer 330 is located between the second layer 310 and the second metal layer 350, and the second metal layer 350 is located between the first layer 330 and the third layer 320. In the illustrated embodiment, the thermal interface component 300 does not comprise any layers other than the layers depicted in FIG. 3. Accordingly, adjacent layers and structures shown in FIG. 3 can be directly bonded to each other (e.g., via a covalent bond, such as, for example and without limitation, silicon carbide bonds and metal carbide bonds), or at least in direct contact with each other.

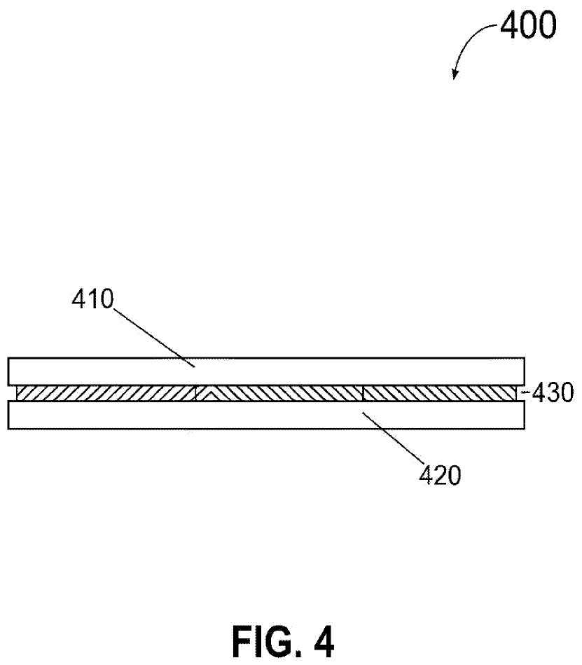

FIG. 4 is a schematic diagram of a cross-sectional view of a thermal interface component 400, according to some embodiments. As shown in FIG. 4, the thermal interface component 400 includes a first layer 430 disposed directly between a second layer 410 and a third layer 420, without an intervening layer. In this embodiment, opposing surfaces of the first layer 430 are directly bonded to the second and third layers 410, 420, for example by covalent bonding between polished bonding surfaces, such as may be achieved using surface-activated bonding as described herein.

In further reference to FIG. 4, in some embodiments, the first layer 430 is located between the second layer 410 and the third layer 420. In the illustrated embodiment, the thermal interface component 400 does not comprise any layers other than the layers depicted in FIG. 4. Accordingly, the first layer 430 is directly bonded to the second layer 410 via, for example, a covalent bond, such as, for example and without limitation, a silicon carbide bond. In addition, the first layer 430 is directly bonded to the third layer 420 via, for example, a covalent bond, such as, for example and without limitation, a silicon carbide bond. In some embodiments, the direct covalent bonding illustrated in FIG. 4 is formed using surface preparation and surface-activated bonding processes as described herein.

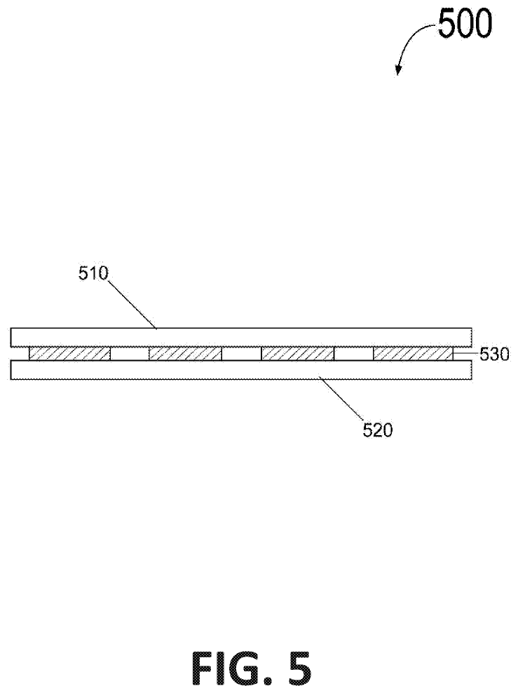

FIG. 5 is a schematic diagram of a cross-sectional view of a thermal interface component 500 according to some embodiments. As shown in FIG. 5, the thermal interface component 500 includes a second layer 510, a third layer 520, and a plurality of diamond segments 530 arranged between the second layer 510 and the third layer 520. The diamond segments 530 collectively form a segmented first layer and may be arranged in a patterned array, with portions of the silicon layers exposed between adjacent diamond segments. The plurality of diamond segments 530 are disposed between the second layer 510 and the third layer 520 and are directly bonded to the silicon layers. Opposing surfaces of the diamond segments 530 may comprise polished bonding surfaces, and the segmented diamond layer may be formed as a patterned or damascene-type structure as described herein.

Although metal layers are not shown in FIG. 5, it will further be appreciated that at least one metal layer can be present, for example, between the second layer 510 and the plurality of diamond segments 530, between the third layer 520 and the plurality of diamond segments 530, or both.

In the illustrated embodiment, the plurality of diamond segments 530 have a quadrilateral shape and is arranged in a periodic ordered array. While nine diamond segments are shown, it will be appreciated that the thermal interface component 500 can include more diamond segments or fewer diamond segments, as disclosed herein, without departing from the scope of this disclosure. The plurality of diamond segments 530 are shown located between the second layer 510 and the third layer 520. Each of the plurality of diamond segments 530 is shown spaced apart from each other, such that, at least a portion of a surface of the second layer 510 and at least a portion of a surface of the third layer 520 is exposed between the plurality of diamond segments 530. In addition, each of the plurality of diamond segments 530 (i.e., opposing surfaces of each diamond segment) is shown directly bonded to the second layer 510 and to the third layer 520 via, for example, a covalent bond, such as, for example and without limitation, a silicon carbide bond. Together the plurality of diamond segments 530 can form a diamond layer, such as, a damascene structure, or a diamond layer.

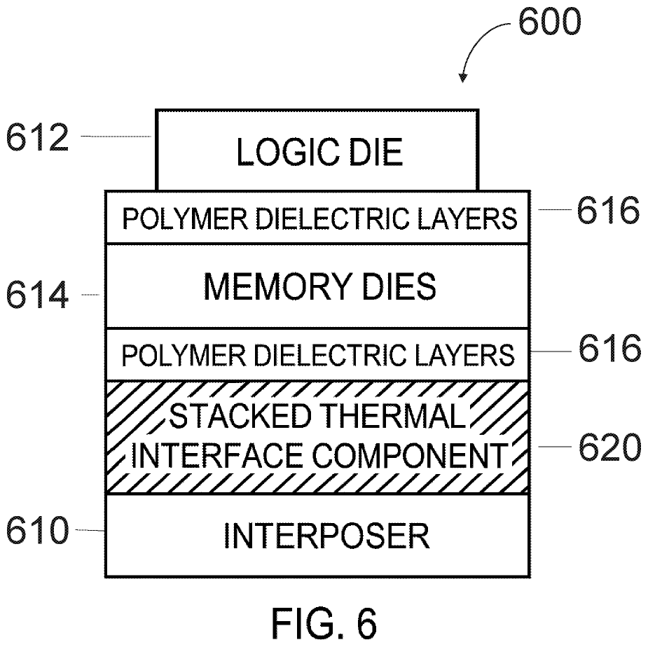

In some embodiments, as illustrated in FIG. 6, a semiconductor device 600 includes a plurality of semiconductor dies arranged within a device structure and supported by an interposer 610. The plurality of semiconductor dies may include one or more functional dies (e.g. logic or memory dies 612, 614) arranged in a stacked or laterally adjacent configuration, with one or more dielectric layers 616 disposed between adjacent dies or between dies and other structural elements. The interposer 610 may provide mechanical support, electrical routing, and thermal conduction within the semiconductor device, and may be formed from silicon, glass, ceramic, or another suitable substrate material.

In the embodiment of FIG. 6, a stacked thermal interface component 620, as described herein according to the various embodiments) is disposed between at least one semiconductor die and an adjacent layer of the device structure. The stacked thermal interface component 620 may be positioned to provide thermal coupling between a semiconductor die (e.g. memory die 612) and the interposer 610 or another adjacent layer, thereby facilitating heat transfer away from the semiconductor die during operation. The stacked thermal interface component 620 may comprise any of the thermal interface component structures as described herein according to the various embodiments. Although a particular arrangement of dies 612, 614, dielectric layers 616, and the stacked thermal interface component 620 is illustrated in FIG. 6, it will be appreciated that the relative ordering, number, and placement of these elements may be varied without departing from the scope of the present disclosure.

Any one or more of the embodiments disclosed herein shall be understood to be combinable without departing from the scope or spirit of the disclosure.

### ASPECTS

Various Aspects are described below. It is to be understood that any one or more of the features recited in the following Aspect(s) can be combined with any one or more other Aspect(s).
Aspect 1 is a thermal interface component for a semiconductor device packaging structure, the thermal interface component comprising a first layer comprising a thermal interface material having a thermal conductivity of at least 200 W·m⁻¹·K⁻¹; and a second layer having a thermal conductivity from 0.1% to 80% of the thermal conductivity of the first layer, wherein the first layer is supported by the second layer, a thickness of the first layer is greater than a thickness of the second layer, and the thermal interface component is dimensioned for integration into a semiconductor device packaging structure.
Aspect 2 is the thermal interface component of Aspect 1, wherein the first layer comprises silicon carbide, diamond, aluminum nitride, or boron nitride.
Aspect 3 is the thermal interface component of any of Aspects 1-2, further comprising a third layer disposed on a side of the first layer opposite the second layer such that the first layer is disposed between the second layer and the third layer.
Aspect 4 is the thermal interface component of Aspect 3, wherein each of the second layer and the third layer independently comprise silicon, silicon carbide, aluminum nitride, gallium nitride, boron nitride, or diamond.
Aspect 5 is the thermal interface component of any of Aspects 1-4, wherein the first layer comprises diamond.
Aspect 6 is the thermal interface component of Aspect 5, wherein the diamond layer comprises a plurality of diamond segments spaced apart from each other.
Aspect 7 is the thermal interface component of Aspect 5, wherein the first layer is a diamond layer comprising a continuous diamond surface.
Aspect 8 is the thermal interface component of any of Aspects 5-7, wherein the diamond comprises monocrystalline diamond or polycrystalline diamond.
Aspect 9 is the thermal interface component of any of Aspects 1-4, wherein the first layer comprises silicon carbide.
Aspect 10 is the thermal interface component of Aspect 9, wherein the silicon carbide is polycrystalline silicon carbide.
Aspect 11 is the thermal interface component of any of Aspects 1-10, wherein the first layer has a thickness in a range of 1 μm to 1000 μm.
Aspect 12 is the thermal interface component of Aspect 11, wherein the first layer has a thickness in a range of 50 μm to 500 μm.
Aspect 13 is the thermal interface component of any of Aspects 3-12, wherein the first layer is directly bonded to and in contact with at least one of the second layer or the third layer.
Aspect 14 is the thermal interface component of any of Aspects 3-13, further comprising an intervening layer disposed between the first layer and at least one of the second layer or the third layer.
Aspect 15 is the thermal interface component of Aspect 14, wherein the intervening layer is a metal layer.
Aspect 16 is the thermal interface component of any of Aspects 1-15, wherein the first layer has a surface roughness (Ra) ranging from 0.1 nm to 1 nm.
Aspect 17 is the thermal interface component of any of Aspects 1-16, wherein the thermal interface component has a total thickness variation (TTV) of 5 μm or less across the thermal interface component parallel to a surface of the thermal interface component.
Aspect 18 is the thermal interface component of Aspect 17, wherein the thermal interface component has a local thickness variation (LTV) of 1 μm or less over a 10 mm gauge length.
Aspect 19 is the thermal interface component of any of Aspects 1-18, wherein the thermal interface component exhibits a through-thickness thermal resistance of 0.10 K/W or less for a 10 mm ×10 mm footprint under steady-state thermal loading.
Aspect 20 is a semiconductor device comprising a thermal interface component having a first layer comprising a thermal interface material having a thermal conductivity of at least 200 W·m⁻¹·K⁻¹, and at least a second layer having a thermal conductivity from 0.1% to 80% of the thermal conductivity of the first layer, wherein the second layer supports the first layer and a thickness of the first layer is greater than a thickness of the second layer.
Aspect 21 is the semiconductor device of Aspect 20, wherein the first layer comprises silicon carbide or diamond.
Aspect 22 is the semiconductor device of any of Aspects 20-21, further comprising a third layer disposed on a side of the first layer opposite the second layer such that the first layer is disposed between the second layer and the third layer.
Aspect 23 is the semiconductor device of any of Aspects 20-22, wherein the thermal interface component has a total thickness variation (TTV) of 5 μm or less across the thermal interface component parallel to a surface of the thermal interface component.
Aspect 24 is the semiconductor device of Aspect 23, wherein the thermal interface component has a local thickness variation (LTV) of 1 μm or less over a 10 mm gauge length.
Aspect 25 is the semiconductor device of any of Aspects 20-24, wherein the thermal interface component exhibits a through-thickness thermal resistance of 0.10 K/W or less for a 10 mm ×10 mm footprint under steady-state thermal loading.
Aspect 26 is the semiconductor device of any of Aspects 20-25, wherein the semiconductor device comprises a semiconductor packaging stack including a plurality of semiconductor dies and one or more packaging layers, and wherein the thermal interface component is disposed within the semiconductor packaging stack.
Aspect 27 is the semiconductor device of Aspect 26, wherein the semiconductor packaging stack comprises at least one logic die and one or more memory dies stacked with one or more polymer dielectric layers, and wherein the thermal interface component is disposed between at least one of the logic die or the memory dies and an adjacent layer of the semiconductor packaging stack.
Aspect 28 is the semiconductor device of Aspect 27, wherein the semiconductor packaging stack comprises a graphics processing unit (GPU) or computational processing unit (CPU), one or more high-bandwidth memory (HBM) dies, and polymer dielectric redistribution layers, and wherein the thermal interface component is thermally coupled to at least one of the GPU or the HBM dies.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respect, only illustrative. Changes may be made in details, particularly in matters of shape, size, and arrangement of parts without exceeding the scope of the disclosure. The disclosure's scope is, of course, defined in the language in which the appended claims are expressed.

What is claimed is:

1. A thermal interface component for a semiconductor device packaging structure, the thermal interface component comprising:
(a) a first layer comprising a thermal interface material having a thermal conductivity of at least 200 W·m⁻¹·K⁻¹; and
(b) a second layer having a thermal conductivity from 0.1% to 80% of the thermal conductivity of the first layer, wherein
the first layer is supported by the second layer,
a thickness of the first layer is greater than a thickness of the second layer, and
the thermal interface component is dimensioned for integration into a semiconductor device packaging structure.

2. The thermal interface component of claim 1, wherein the first layer comprises silicon carbide, diamond, aluminum nitride, or boron nitride.

3. The thermal interface component of claim 1, further comprising a third layer disposed on a side of the first layer opposite the second layer such that the first layer is disposed between the second layer and the third layer.

4. The thermal interface component of claim 3, wherein each of the second layer and the third layer independently comprise silicon, silicon carbide, aluminum nitride, gallium nitride, boron nitride, or diamond.

5. The thermal interface component of claim 1, wherein the first layer comprises diamond.

6. The thermal interface component of claim 5, wherein the diamond layer comprises a plurality of diamond segments spaced apart from each other.

7. The thermal interface component of claim 5, wherein the first layer is a diamond layer comprising a continuous diamond surface.

8. The thermal interface component of claim 5, wherein the diamond comprises monocrystalline diamond or polycrystalline diamond.

9. The thermal interface component of claim 1, wherein the first layer comprises silicon carbide.

10. The thermal interface component of claim 9, wherein the silicon carbide is polycrystalline silicon carbide.

11. The thermal interface component of claim 1, wherein the first layer has a thickness in a range of 1 μm to 1000 μm.

12. The thermal interface component of claim 11, wherein the first layer has a thickness in a range of 50 μm to 500 μm.

13. The thermal interface component of claim 3, wherein the first layer is directly bonded to and in contact with at least one of the second layer or the third layer.

14. The thermal interface component of claim 3, further comprising an intervening layer disposed between the first layer and at least one of the second layer or the third layer.

15. The thermal interface component of claim 14, wherein the intervening layer is a metal layer.

16. The thermal interface component of claim 1, wherein the first layer has a surface roughness (Ra) ranging from 0.1 nm to 1 nm.

17. The thermal interface component of claim 1, wherein the thermal interface component has a total thickness variation (TTV) of 5 μm or less across the thermal interface component parallel to a surface of the thermal interface component.

18. The thermal interface component of claim 17, wherein the thermal interface component has a local thickness variation (LTV) of 1 μm or less over a 10 mm gauge length.

19. The thermal interface component of claim 1, wherein the thermal interface component exhibits a through-thickness thermal resistance of 0.10 K/W or less for a 10 mm×10 mm footprint under steady-state thermal loading.

20. A semiconductor device comprising:
a thermal interface component having,
(a) a first layer comprising a thermal interface material having a thermal conductivity of at least 200 W·m⁻¹·K⁻¹, and
(b) at least a second layer having a thermal conductivity from 0.1% to 80% of the thermal conductivity of the first layer, wherein
the second layer supports the first layer and
a thickness of the first layer is greater than a thickness of the second layer.
